(19) United States
(12) Patent Application Publication
(10) Pub. No.: US 2026/0143807 A1
(43) Pub. Date: May 21, 2026

(54) SEMICONDUCTOR DEVICE AND FABRICATING METHOD THEREOF

(71) Applicant: TAIWAN SEMICONDUCTOR MANUFACTURING COMPANY, LTD., Hsinchu (TW)

(72) Inventors: Hung-Li CHIANG, Taipei City (TW); Chun-Yen LIN, Hsinchu City (TW); Wei-Cheng LIN, Taichung City (TW); Jiann-Tyng TZENG, Hsinchu City (TW)

(73) Assignee: TAIWAN SEMICONDUCTOR MANUFACTURING COMPANY, LTD., Hsinchu (TW)

(21) Appl. No.: 18/955,346

(22) Filed: Nov. 21, 2024

(51) Int. Cl. H01L 27/092; H01L 21/8238; H01L 23/522; H01L 23/528

(52) U.S. Cl. CPC H10D 84/856; H10D 84/0186; H10D 84/0188; H10D 84/038; H10W 20/42; H10W 20/43

(57) ABSTRACT

A device includes a first layer, a second layer and a first conductive segment. The first layer corresponds to transistors of a first conductive type. The second layer corresponds to transistors of a second conductive type different from the first conductive type. The first conductive segment is disposed between and coupled to the first layer and the second layer, and configured to connect a first logic cell to a second logic cell. Each of the first logic cell and the second logic cell corresponds to the first layer and the second layer.

### BACKGROUND

A semiconductor device includes multiple logic cells. The logic cells are connected to each other through routing resource in metal layer, such as metal-zero (M0) layer. In monolithic CFET with an aggressive scaled cell height, the routing resource may be limited due to the lack of sufficient top M0 tracks and bottom M0 tracks.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a cross sectional view of a semiconductor device, illustrated in accordance with some embodiments of the present disclosure.

FIG. 1B is a schematic diagram of a layout view of the semiconductor device, illustrated in accordance with some embodiments of the present disclosure.

FIG. 1C is a schematic diagram of a three-dimensional view of the semiconductor device, illustrated in accordance with some embodiments of the present disclosure.

FIG. 2 is a circuit diagram of a semiconductor device, illustrated in accordance with some embodiments of the present disclosure.

FIG. 3A is a schematic diagram of a cross sectional view of a semiconductor device, illustrated in accordance with some embodiments of the present disclosure.

FIG. 3B is a schematic diagram of a layout view of the semiconductor device, illustrated in accordance with some embodiments of the present disclosure.

FIG. 4 is a circuit diagram of a semiconductor device, illustrated in accordance with some embodiments of the present disclosure.

FIG. 5A is a schematic diagram of a cross sectional view of a semiconductor device, illustrated in accordance with some embodiments of the present disclosure.

FIG. 5B is a schematic diagram of a cross sectional view of a semiconductor device, illustrated in accordance with some embodiments of the present disclosure.

FIG. 5C is a schematic diagram of a cross sectional view of a semiconductor device, illustrated in accordance with some embodiments of the present disclosure.

FIG. 6A is a schematic diagram of a cross sectional view of a semiconductor device, illustrated in accordance with some embodiments of the present disclosure.

FIG. 6B is a schematic diagram of a layout view of the semiconductor device, illustrated in accordance with some embodiments of the present disclosure.

FIG. 7 is a flowchart diagram of a method for fabricating the memory devices described above, illustrated in accordance with some embodiments of the present disclosure.

FIG. 8 is a schematic view of a system for designing and manufacturing at least one of the semiconductor devices described above, illustrated in accordance with some embodiments of the present disclosure.

FIG. 9 is a block diagram of an integrated circuit (IC)/semiconductor device manufacturing system, and an IC manufacturing flow associated therewith, illustrated in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

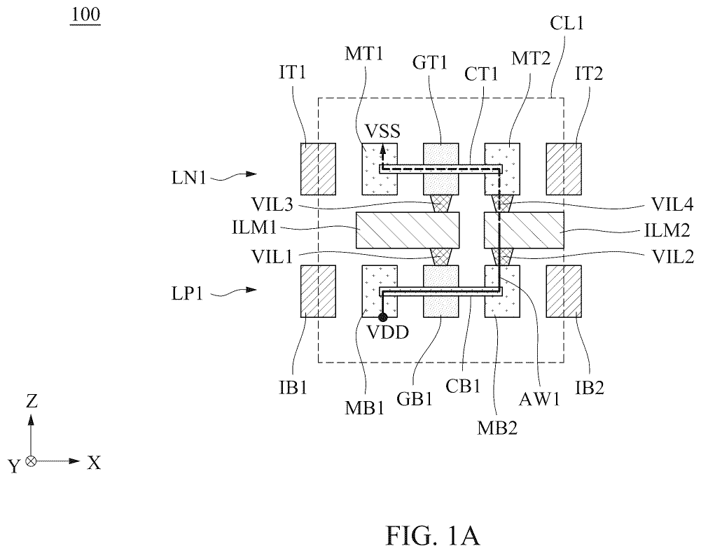

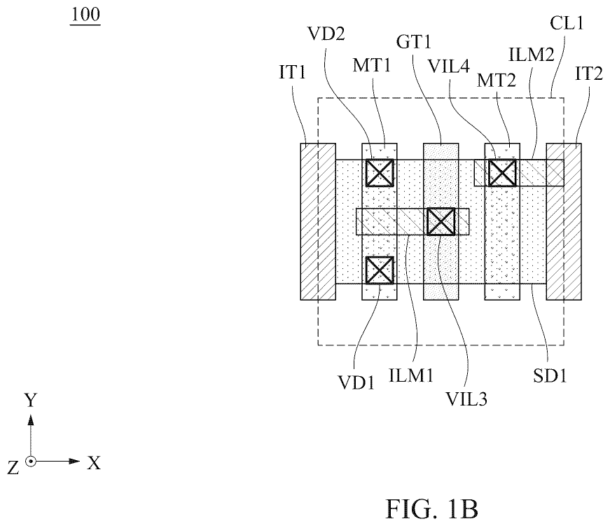

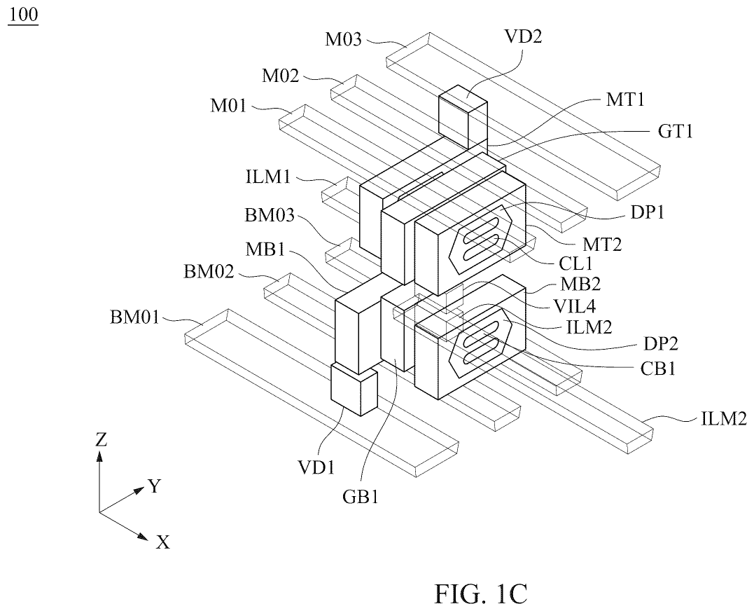

FIG. 1A is a schematic diagram of a cross sectional view of a semiconductor device 100, illustrated in accordance with some embodiments of the present disclosure. As illustratively shown in FIG. 1A, the semiconductor device 100 includes layers LN1, LP1, conductive segments ILM1-ILM2 and via structures VIL1-VIL4.

In some embodiments, the semiconductor device 100 corresponds to a complementary field-effect transistor (CFET) structure. The layers LN1 and LP1 correspond to transistors of different conductive type. For example, the layer LN1 includes N-type transistors, and the layer LP1 includes P-type transistors.

Along a Z direction, each of the conductive segments ILM1-ILM2 and the via structures VIL1-VIL4 is disposed between the layers LN1 and LP1. The conductive segment ILM1 is coupled to and disposed between the via structures VIL1 and VIL3. The conductive segment ILM2 is coupled to and disposed between the via structures VIL2 and VIL4. Along an X direction, the conductive segments ILM1 and ILM2 are separated from each other. In some embodiments, the conductive segments ILM1-ILM2 are referred to as inter-layer metal. In FIG. 1A, a Y direction points into the paper. In some embodiments, the X direction, the Y direction and the Z direction are perpendicular with each other.

As illustratively shown in FIG. 1A, the layer LN1 includes a channel structure CT1, conductive segments MT1, MT2, a gate structure GT1 and isolation structures IT1, IT2. Along the X direction, the isolation structure IT1, the conductive segment MT1, the gate structure GT1, the conductive segment MT2 and the isolation structure IT2 are arranged in order. The channel structure CT1 elongated through the gate structure GT1 and is coupled to each of the conductive segments MT1 and MT2.

Similarly, the layer LP1 includes a channel structure CB1, conductive segments MB1, MB2, a gate structure GB1 and isolation structures IB1 and IB2. Along the X direction, the isolation structure IB1, the conductive segment MB1, the gate structure GB1, the conductive segment MB2 and the isolation structure IB2 are arranged in order. The channel structure CB1 elongated through the gate structure GB1 and is coupled to each of the conductive segments MB1 and MB2.

In some embodiments, the semiconductor device 100 includes a logic cell CL1. The channel structures CB1, CT1, the conductive segments MB1, MB2, MT1, MT2 and the gate structures GT1, GB1 are included in the logic cell CL1. The isolation structures IT1, IT2, IB1 and IB2 are located at boundaries of the logic cell CL1, to isolate the logic cell CL1 from other cells of the semiconductor device 100.

In some embodiments, the via structure VIL1 couples the conductive segment ILM1 to the gate structure GB1. The via structure VIL2 couples the conductive segment ILM2 to the conductive segment MB2. The via structure VIL3 couples the conductive segment ILM1 to the gate structure GT1. The via structure VIL4 couples the conductive segment ILM2 to the conductive segment MT2.

In some embodiments, the conductive segments MB1 and MT1 are configured to receive reference voltage signals VDD and VSS, respectively. In some embodiments, the reference voltage signals VDD and VSS has a power voltage level and a ground voltage level, respectively. The power voltage level is higher than the ground voltage level.

As illustratively shown in FIG. 1A, during operations, the reference voltage signals VDD and VSS are transmitted along an arrow AW1. Alternatively stated, the reference voltage signal VDD is transmitted from the conductive segment MB1, through the channel structure CB1 and the via structure VIL2 in order, to the conductive segment ILM2. The reference voltage signal VSS is transmitted from the conductive segment MT1, through the channel structure CT1 and the via structure VIL4 in order, to the conductive segment ILM2.

FIG. 1B is a schematic diagram of a layout view of the semiconductor device 100, illustrated in accordance with some embodiments of the present disclosure. In FIG. 1B, the Z direction points out from the paper. As illustratively shown in FIG. 1B, the conductive segment ILM1 is overlapped with each of the conductive segment MT1 and the gate structure GT1. The conductive segment ILM2 is overlapped with the conductive segment MT2. The semiconductor device 100 further includes a source/drain structure SD1 and via structures VD1, VD2.

Referring to FIG. 1A and FIG. 1B, the channel structure CT1 is included in the source/drain structure SD1. The via structure VD1 is coupled to the conductive segment MB1, and the via structure VD2 is coupled to the conductive segment MT1. In some embodiments, the via structures VD1 and VD2 are configured to transmit the reference voltage signals VDD and VSS, respectively. Along the Z direction, the via structure VD1 is disposed below the conductive segment MB1, and the via structure VD2 is disposed above the conductive segment MT1.

FIG. 1C is a schematic diagram of a three-dimensional view of the semiconductor device 100, illustrated in accordance with some embodiments of the present disclosure. As illustratively shown in FIG. 1C, the semiconductor device 100 further includes doped structures DP1, DP2, and conductive segments M01-M03, BM01-BM03.

In some embodiments, each of the conductive segments M01-M03 and BM01-BM03 elongate along the X direction. Along the Y direction, the conductive segments M01-M03 are disposed above the layer LN1, and the conductive segments M01-M03 are disposed below the layer LP1. Along the Y direction, the conductive segments M01-M03 are arranged in order and separated from each other, and the conductive segments BM01-BM03 are arranged in order and separated from each other.

Referring to FIG. 1A to FIG. 1C, the conductive segment M03 is configured to transmit the reference voltage signal VSS through the via structure VD2 to the conductive segment MT1. The conductive segment BM01 is configured to transmit the reference voltage signal VDD to through the via structure VD1 the conductive segment MB1.

As illustratively shown in FIG. 1C, the doped structure DP1 surrounds and is coupled to the channel structure CT1. The conductive segment MT2 surrounds and is coupled to the doped structure DP1. The doped structure DP2 surrounds and is coupled to the channel structure CB1. The conductive segment MB2 surrounds and is coupled to the doped structure DP2. In some embodiments, one of the doped structures DP1 and DP2 is implemented by N-type doped epitaxy material, and the other one of the doped structures DP1 and DP2 is implemented by P-type doped epitaxy material.

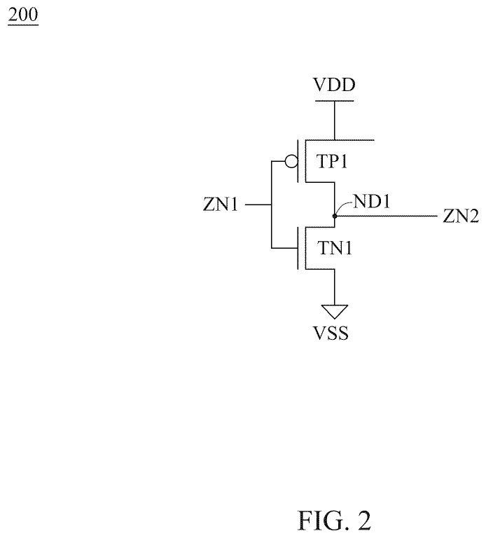

FIG. 2 is a circuit diagram of a semiconductor device 200, illustrated in accordance with some embodiments of the present disclosure. As illustratively shown in FIG. 2, the semiconductor device 200 includes switches TP1 and TN1. Each of control terminals of the switches TP1 and TN1 is configured to receive a voltage signal ZN1. A terminal of the switch TP1 is configured to receive the reference voltage signal VDD, and another terminal of the switch TP1 is coupled to a node ND1. A terminal of the switch TN1 is configured to receive the reference voltage signal VSS, and another terminal of the switch TN1 is coupled to the node ND1.

In some embodiments, the semiconductor device 200 is configured to operate as an inverter logic cell. The switches TP1 and TN1 are respectively implemented by a P-type transistor and an N-type transistor. During operation, the semiconductor device 200 is configured to generate a voltage signal ZN2 at the node ND1 according to the voltage signal ZN1.

Referring to FIG. 1A to FIG. 2, the semiconductor device 200 is implemented by the semiconductor device 100 in some embodiments. The switch TP1 is implemented by the gate structure GB1 and the conductive segments MB1, MB2. The switch TN1 is implemented by the gate structure GT1 and the conductive segments MT1, MT2. The node ND1 corresponds to the conductive segment ILM2. Alternatively stated, each of the gate structures GB1 and GT1 is configured to receive the voltage signal ZN1 from the conductive segment ILM1. The conductive segment ILM2 is configured to output the voltage signal ZN2, and is disposed between the switches TP1 and TN1. Accordingly, the layer LN1 includes the switch TN1, and the layer LP1 includes the switch TP1.

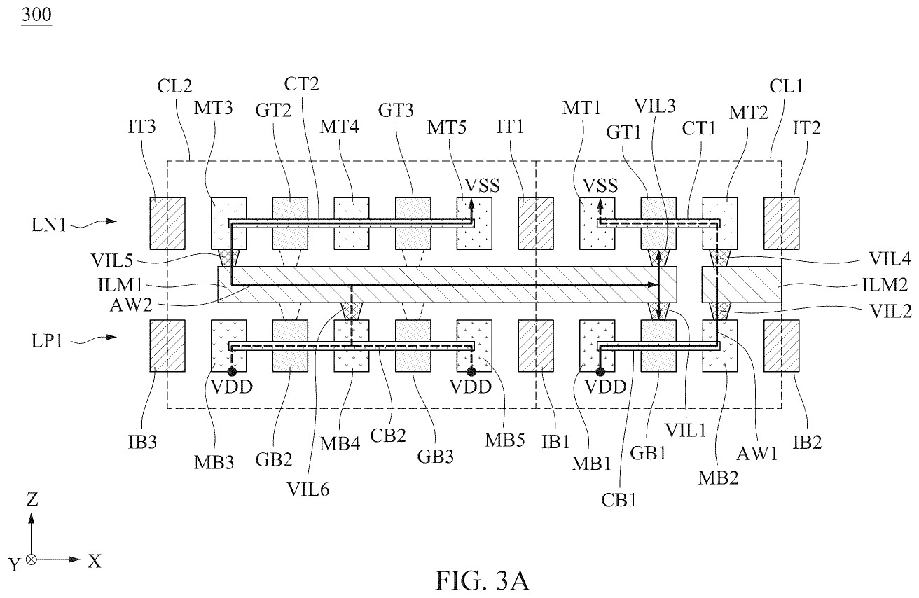

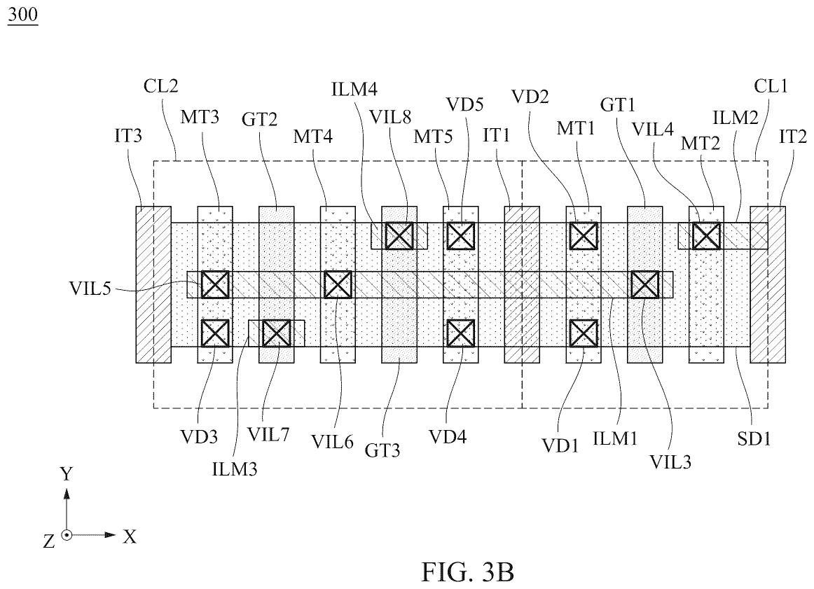

FIG. 3A is a schematic diagram of a cross sectional view of a semiconductor device 300, illustrated in accordance with some embodiments of the present disclosure. Referring to FIG. 1A and FIG. 3A, the semiconductor device 300 is an alternative embodiment of the semiconductor device 100. FIG. 3A follows a similar labeling convention to that of FIG. 1A. For brevity, the discussion will focus more on differences between the semiconductor device 300 and the semiconductor device 100 than on similarities.

Compared to the semiconductor device 100, the semiconductor device 300 further includes via structures VIL5, VIL6, channel structures CT2, CB2, conductive segments MT3-MT5, MB3-MB5, gate structures GT2, GT3, GB2, GB3 and isolation structures IT3, IB3. As illustratively shown in FIG. 3A, the channel structure CT2, the conductive segments MT3-MT5, the gate structures GT2, GT3 and isolation structures IT3 are included in the layer LN1. The channel structure CB2, the conductive segments MB3-MB5, the gate structures GB2, GB3 and isolation structures IB3 are included in the layer LP1.

Along the X direction, the isolation structure IT3, the conductive segment MT3, the gate structure GT2, the conductive segment MT4, the gate structure GT3, the conductive segment MT5 and the isolation structure IT1 are arranged in order. The channel structure CT2 elongated through the gate structures GT2, GT3 and the conductive segment MT4, and is coupled to each of the conductive segments MT3 and MT5.

Similarly, along the X direction, the isolation structure IB3, the conductive segment MB3, the gate structure GB2, the conductive segment MB4, the gate structure GB3, the conductive segment MB5 and the isolation structure IB1 are arranged in order. The channel structure CB2 elongated through the gate structures GB2, GB3 and the conductive segment MB4, and is coupled to each of the conductive segments MB3 and MB5.

Compared to the semiconductor device 100 shown in FIG. 1A, the semiconductor device 300 further includes a logic cell CL2. The channel structures CB2, CT2, the conductive segments MB3-MB5, MT3-MT5 and the gate structures GT2, GT3, GB2, GB3 are included in the logic cell CL2. The isolation structures IT1, IT3, IB1 and IB3 are located at boundaries of the logic cell CL1, to isolate the logic cell CL1 from other cells of the semiconductor device 300. For example, the isolation structure IT1 is configured to isolate the conductive segments MT5 and MT1 from each other, and the isolation structure IB1 is configured to isolate the conductive segments MB5 and MB1 from each other.

In some embodiments, the via structure VIL5 couples the conductive segment ILM1 to the conductive segment MT3, and the via structure VIL6 couples the conductive segment ILM1 to the conductive segment MB4. Each of the conductive segments MB3 and MB5 is configured to receive reference voltage signal VDD. The conductive segment MT5 is configured to receive reference voltage signal VSS.

As illustratively shown in FIG. 3A, during operations, the reference voltage signals VDD and VSS are transmitted along an arrow AW2. Alternatively stated, the reference voltage signal VDD is transmitted from the conductive segment MB3, through the channel structure CB2 and the via structure VIL6 in order, to the conductive segment ILM1, and from the conductive segment MB5, through the channel structure CB2 and the via structure VIL6 in order, to the conductive segment ILM1. The reference voltage signal VSS is transmitted from the conductive segment MT5, through the channel structure CT2 and the via structure VIL5 in order, to the conductive segment ILM1.

It is noted that the conductive segment ILM1 is configured to connect the logic cells CL1 and CL2 with each other for inter-cell routing. In some embodiments, the conductive segment ILM1 is referred to as an inter-cell connection.

In some approaches, in monolithic complementary field-effect transistor (CFET) with an aggressive scaled cell height, the routing resource may be limited due to the lack of sufficient top metal tracks and bottom metal tracks.

Compared to above approaches, in some embodiments of present disclosure, the inter-layer metal, such as the conductive segment ILM1 is used for inter-cell routing, to connect the cells CL1 and CL2. As a result, compatibility with sequential CFET is increased, and the routing resource is higher.

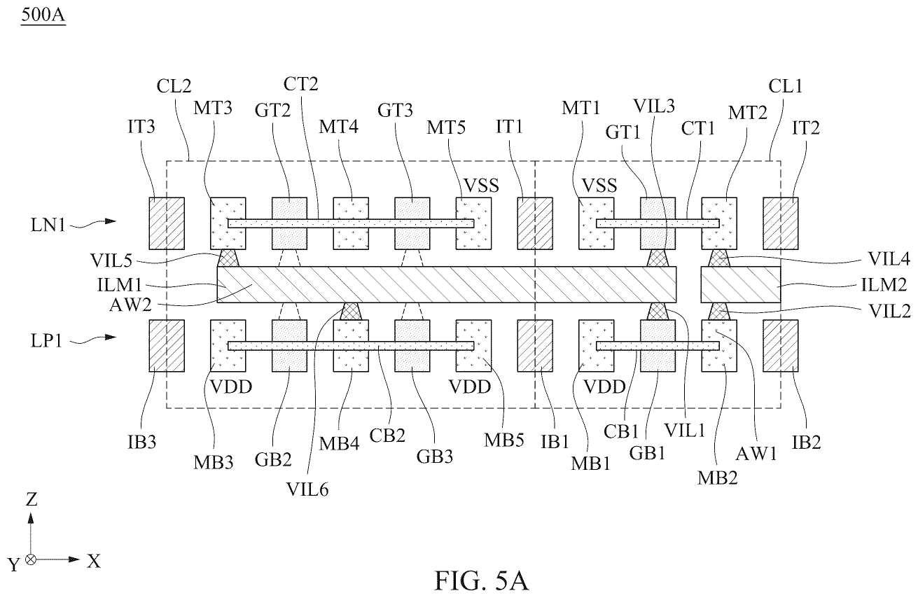

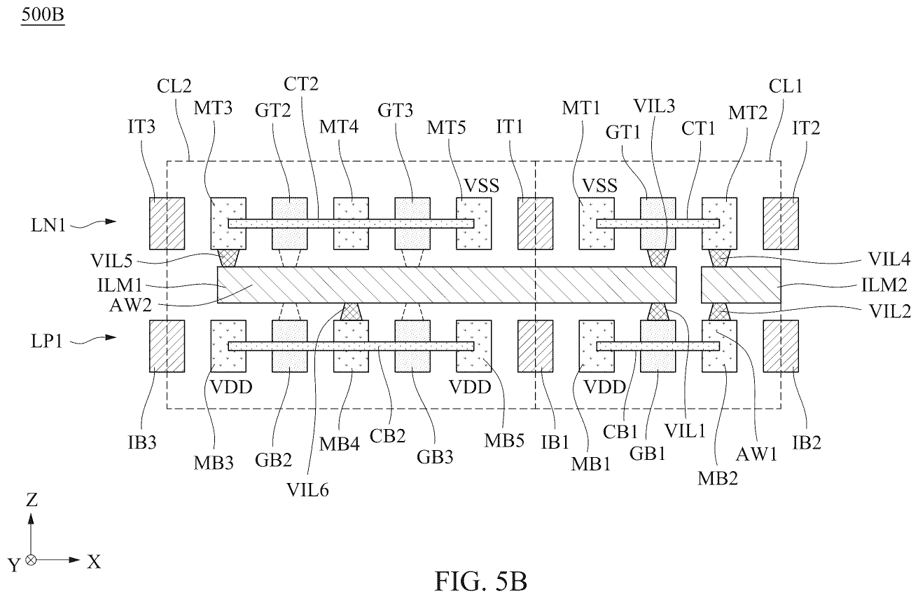

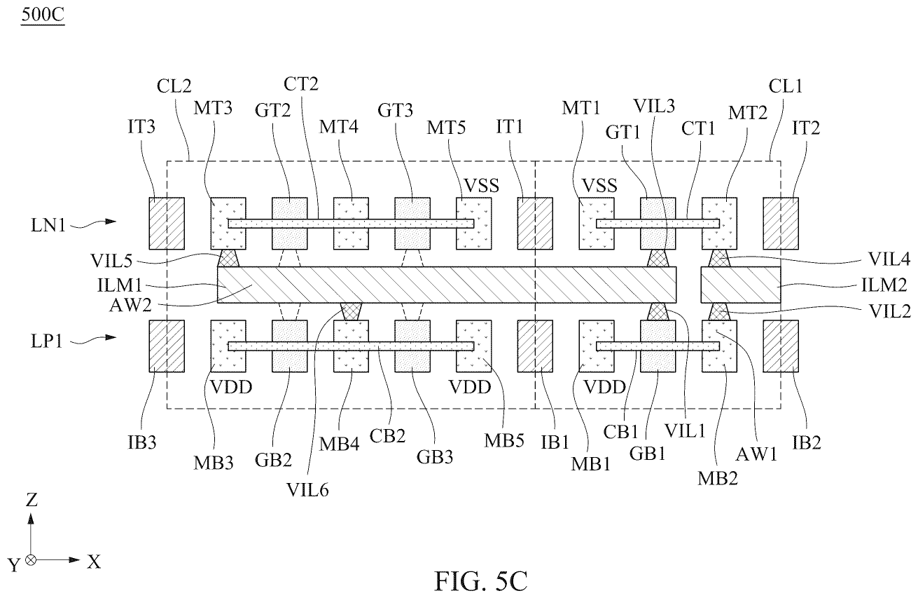

Along the Z direction, each of the via structures VIL1-VIL6 has two opposite edges. In the embodiment shown in FIG. 3A, the upper edges of the via structures VIL1-VIL6 are longer than the lower edges of the via structures VIL1-VIL6. However, the embodiments of present disclosure are not limited to this. In response to various manufacturing processes, the edges of the via structures VIL1-VIL6 have various relationships. Further details of the various relationships are described below with the embodiments associated with FIG. 5A to FIG. 5C.

FIG. 3B is a schematic diagram of a layout view of the semiconductor device 300, illustrated in accordance with some embodiments of the present disclosure. Referring to FIG. 1B and FIG. 3B, the semiconductor device 300 is an alternative embodiment of the semiconductor device 100. FIG. 3B follows a similar labeling convention to that of FIG. 1B. For brevity, the discussion will focus more on differences between the semiconductor device 300 and the semiconductor device 100 than on similarities.

As illustratively shown in FIG. 3B, the conductive segment ILM1 is overlapped with each of the conductive segments MT1, MT3-MT5, the isolation structure IT1 and the gate structures GT1-GT3. Referring to FIG. 1B and FIG. 3B, compared to the semiconductor device 100, the semiconductor device 300 further includes via structures VD3-VD5. VIL7, VIL8, and conductive segments ILM3, ILM4. The gate structures GT2 and GT3 cross over the conductive segments ILM3 and ILM4, respectively. Along the Y direction, the conductive segment ILM1 is disposed between and separated from the conductive segments ILM3 and ILM4.

Referring to FIG. 3A and FIG. 3B, the via structures VD3-VD5 are coupled to the conductive segments MB3, MB5 and MT5, respectively. In some embodiments, the via structures VD3 and VD4 are configured to transmit the reference voltage signal VDD to the conductive segments MB3 and MB5, and the via structure VD5 is configured to transmit the reference voltage signal VSS to the conductive segment MT5. Along the Z direction, the via structures VD3 and VD4 are disposed below the conductive segments MB3 and MB5, and the via structure VD5 is disposed above the conductive segment MT5.

Furthermore, along the Z direction, each of the conductive segments ILM3 and ILM4 is disposed between the layers LN1 and LP1. In some embodiments, the conductive segment ILM3 is disposed between the gate structures GT2 and GB2, and is coupled to each of the gate structures GT2 and GB2 through the via structure VIL7. The conductive segment ILM4 is disposed between the gate structures GT3 and GB3, and is coupled to each of the gate structures GT3 and GB3 through the via structure VIL8.

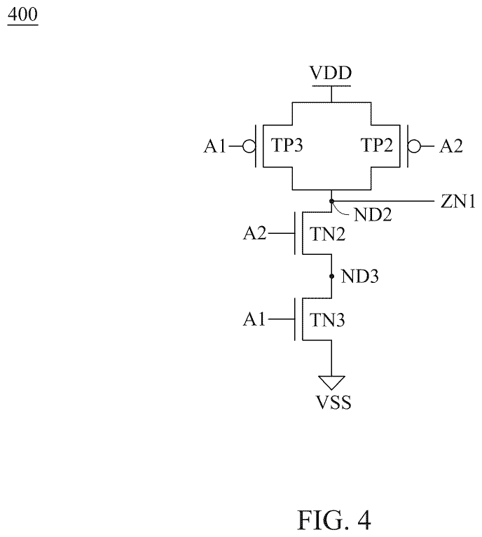

FIG. 4 is a circuit diagram of a semiconductor device 400, illustrated in accordance with some embodiments of the present disclosure. As illustratively shown in FIG. 4, the semiconductor device 400 includes switches TP2, TP3, TN2 and TN3. Each of control terminals of the switches TP2 and TN2 is configured to receive a voltage signal A2. Each of control terminals of the switches TP3 and TN3 is configured to receive a voltage signal A1. A terminal of the switch TP2 is configured to receive the reference voltage signal VDD, and another terminal of the switch TP2 is coupled to a node ND2. A terminal of the switch TP3 is configured to receive the reference voltage signal VDD, and another terminal of the switch TP3 is coupled to the node ND2. Two terminals of the switch TN2 are coupled to nodes ND2 and ND3, respectively. A terminal of the switch TN3 is configured to receive the reference voltage signal VSS, and another terminal of the switch TN1 is coupled to the node ND3.

In some embodiments, the semiconductor device 400 is configured to operate as a NAND logic cell. The switches TP2 and TP3 are implemented by P-type transistors. The switches TN2 and TN3 re implemented by N-type transistors. During operation, the semiconductor device 400 is configured to generate the voltage signal ZN1 at the node ND2 according to the voltage signals A1 and A2.

Referring to FIG. 3A to FIG. 4, the semiconductor device 400 is implemented by the semiconductor device 300 in some embodiments. The switch TP2 is implemented by the gate structure GB2 and the conductive segments MB3, MB4. The switch TP3 is implemented by the gate structure GB3 and the conductive segments MB4, MB5. The switch TN2 is implemented by the gate structure GT2 and the conductive segments MT3, MT4. The switch TN3 is implemented by the gate structure GT3 and the conductive segments MT4, MT5. The node ND2 corresponds to the conductive segment ILM1. The node ND3 corresponds to the conductive segment MT4. Accordingly, the layer LN1 includes each of the switches TN2 and TN3, and the layer LP1 includes each of the switches TP2 and TP3.

In some embodiments, each of the gate structures GB2 and GT2 is configured to receive the voltage signal A2 through the conductive segment ILM3 and the via structure VIL7. Each of the gate structures GB3 and GT3 is configured to receive the voltage signal A1 through the conductive segment ILM4 and the via structure VIL8. The conductive segment ILM1 is configured to transmit the voltage signal ZN1 from the logic cell CL2 to the logic cell CL1. The conductive segment ILM1 is disposed between the switches TP2 and TN2, and between the switches TP3 and TN3.

FIG. 5A is a schematic diagram of a cross sectional view of a semiconductor device 500A, illustrated in accordance with some embodiments of the present disclosure. Referring to FIG. 5A and FIG. 3A, the semiconductor device 500A is an alternative embodiment of the semiconductor device 300. FIG. 5A follows a similar labeling convention to that of FIG. 3A. For brevity, the discussion will focus more on differences between the semiconductor device 500A and the semiconductor device 300 than on similarities.

Compared to the device 300, in the semiconductor device 500A, along the Z direction, the upper edges of the via structures VIL1-VIL6 are shorter than the lower edges of the via structures VIL1-VIL6.

Referring to FIG. 3A and FIG. 5A, in the embodiment shown in FIG. 5A, the conductive segments ILM1 and ILM2 are coupled to the via structures VIL1, VIL2 and VIL6 after the via structures VIL1, VIL2 and VIL6 are formed on the layer LP1, and the layer LN1 is coupled to the via structures VIL3-VIL5 after the via structures VIL3-VIL5 are formed on the conductive segments ILM1 and ILM2.

In contrast, in the embodiment shown in FIG. 5A, the conductive segments ILM1 and ILM2 are coupled to the via structures VIL3-VIL5 after the via structures VIL3-VIL5 are formed on the layer LN1, and the layer LP1 is coupled to the via structures VIL1, VIL2 and VIL6 after the via structures VIL1, VIL2 and VIL6 are formed on the conductive segments ILM1 and ILM2.

FIG. 5B is a schematic diagram of a cross sectional view of a semiconductor device 500B, illustrated in accordance with some embodiments of the present disclosure. Referring to FIG. 5B and FIG. 3A, the semiconductor device 500B is an alternative embodiment of the semiconductor device 300. FIG. 5B follows a similar labeling convention to that of FIG. 3A. For brevity, the discussion will focus more on differences between the semiconductor device 500B and the semiconductor device 300 than on similarities.

Compared to the device 300, in the semiconductor device 500B, along the Z direction, the upper edges of the via structures VIL1, VIL2 and VIL6 are shorter than the lower edges of the via structures VIL1, VIL2 and VIL6, and the upper edges of the via structures VIL3-VIL5 are longer than the lower edges of the via structures VIL3-VIL5.

In the embodiment shown in FIG. 5B, the layer LP1 is coupled to the via structures VIL1, VIL2 and VIL6 after the via structures VIL1, VIL2 and VIL6 are formed on the conductive segments ILM1 and ILM2, and the layer LN1 is coupled to the via structures VIL3-VIL5 after the via structures VIL3-VIL5 are formed on the conductive segments ILM1 and ILM2.

FIG. 5C is a schematic diagram of a cross sectional view of a semiconductor device 500C, illustrated in accordance with some embodiments of the present disclosure. Referring to FIG. 5C and FIG. 3A, the semiconductor device 500C is an alternative embodiment of the semiconductor device 300. FIG. 5C follows a similar labeling convention to that of FIG. 3A. For brevity, the discussion will focus more on differences between the semiconductor device 500C and the semiconductor device 300 than on similarities.

Compared to the device 300, in the semiconductor device 500C, along the Z direction, the upper edges of the via structures VIL1, VIL2 and VIL6 are longer than the lower edges of the via structures VIL1, VIL2 and VIL6, and the upper edges of the via structures VIL3-VIL5 are shorter than the lower edges of the via structures VIL3-VIL5.

In the embodiment shown in FIG. 5C, the conductive segments ILM1 and ILM2 are coupled to the via structures VIL1, VIL2 and VIL6 after the via structures VIL1, VIL2 and VIL6 are formed on the layer LP1, and the conductive segments ILM1 and ILM2 are coupled to the via structures VIL3-VIL5 after the via structures VIL3-VIL5 are formed on the layer LN1.

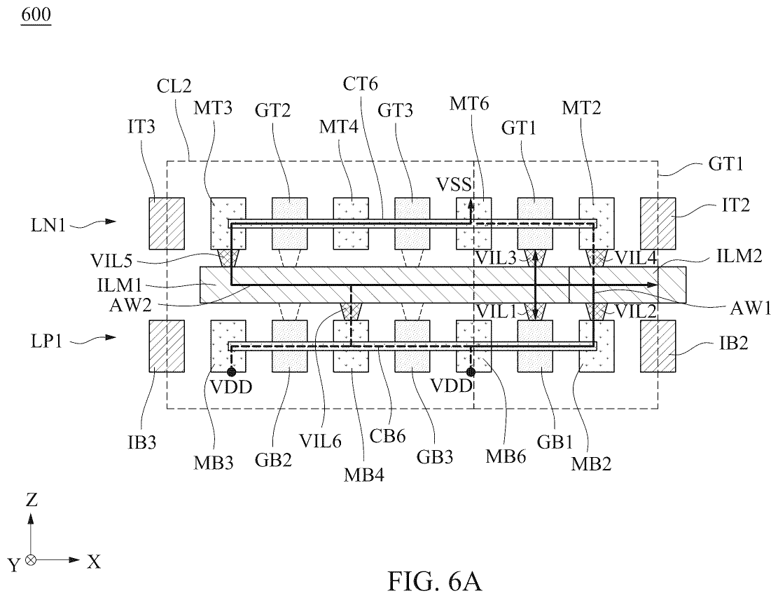

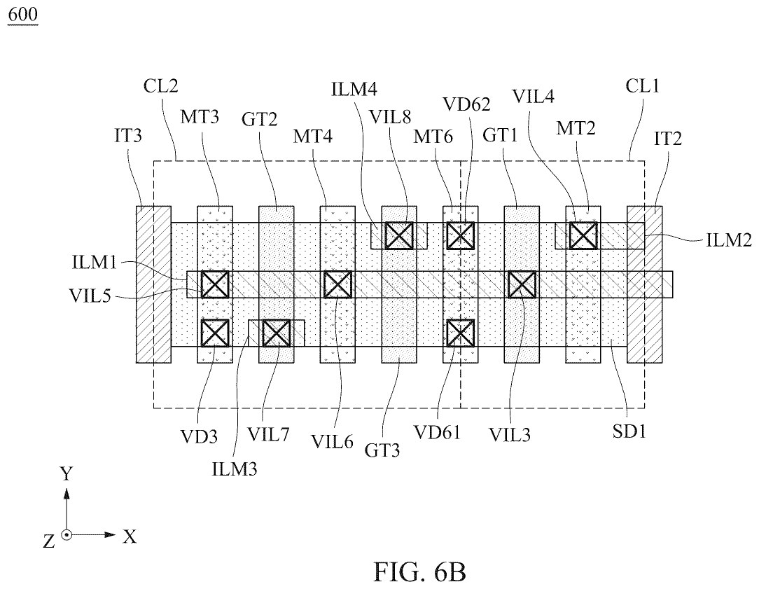

FIG. 6A is a schematic diagram of a cross sectional view of a semiconductor device 600, illustrated in accordance with some embodiments of the present disclosure. Referring to FIG. 6A and FIG. 3A, the semiconductor device 600 is an alternative embodiment of the semiconductor device 300. FIG. 6A follows a similar labeling convention to that of FIG. 3A. For brevity, the discussion will focus more on differences between the semiconductor device 600 and the semiconductor device 300 than on similarities.

Compared to the device 300, the semiconductor device 600 includes conductive segments MT6, MB6 and channel structures CT6, CB6, instead of the conductive segments MT5, MB5, MT1, MB1, isolation structures IT2, IB2 and channel structures CT1, CB1, CT2, CB2.

As illustratively shown in FIG. 6A, the conductive segment MT6 is disposed in the layer LN1, and is disposed between the gate structures GT1 and GT3. The conductive segment MB6 is disposed in the layer LP1, and is disposed between the gate structures GB1 and GB3. The channel structure CT6 extends through the gate structures GT1-GT3 and the conductive segments MT4, MT6, and is coupled to each of the conductive segments MT2 and MT3. The channel structure CB6 extends through the gate structures GB1-GB3 and the conductive segments MB4, MB6, and is coupled to each of the conductive segments MB2 and MB3. Along the Y direction, the conductive segments ILM1 and ILM2 are overlapped and separated from each other. The conductive segments MT6 and MB6 are configured to receive the reference voltage signals VSS and VDD, respectively.

Referring to FIG. 6A, FIG. 2 and FIG. 4, in some embodiments, the switch TN1 is implemented by the conductive segments MT2, MT6 and the gate structure GT1. The switch TP1 is implemented by the conductive segments MB2, MB6 and the gate structure GB1. The switch TN3 is implemented by the conductive segments MT4, MT6 and the gate structure GT3. The switch TP3 is implemented by the conductive segments MB4, MB6 and the gate structure GB3.

FIG. 6B is a schematic diagram of a layout view of the semiconductor device 600, illustrated in accordance with some embodiments of the present disclosure. Referring to FIG. 6B and FIG. 3B, the semiconductor device 600 is an alternative embodiment of the semiconductor device 300. FIG. 6B follows a similar labeling convention to that of FIG. 3B. For brevity, the discussion will focus more on differences between the semiconductor device 600 and the semiconductor device 300 than on similarities.

Compared to the device 300, the semiconductor device 600 includes via structures VD61 and VD62, instead of the via structures VD1, VD2, VD4 and VD5. The conductive segment ILM1 is further overlapped with each of the conductive segment MT2 and the isolation structure IT2.

Referring to FIG. 6A and FIG. 6B, the via structure VD61 is configured to transmit the reference voltage signal VDD to the conductive segment MB6. The via structure VD62 is configured to transmit the reference voltage signal VSS to the conductive segment MT6. Along the Z direction, the via structure VD61 is disposed below the conductive segment MB6, and the via structure VD62 is disposed below the conductive segment MT6.

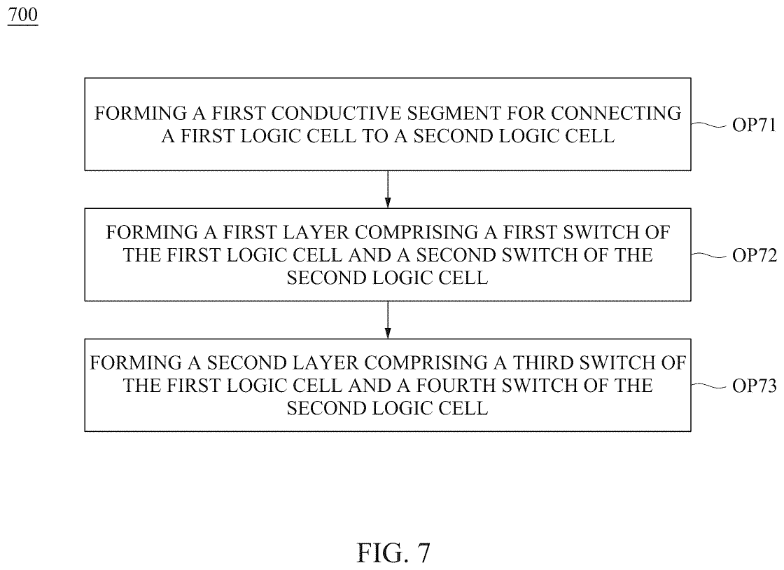

FIG. 7 is a flowchart diagram of a method 700 for fabricating the semiconductor devices described above, illustrated in accordance with some embodiments of the present disclosure. The method 700 includes operations OP71-OP73.

In some embodiments, the operations OP71-OP73 are performed in order. However, the embodiments of present disclosure are not limited to this. Various sequences of performing the operations OP71-OP73 are contemplated as within the scope of present disclosure. For example, the operations OP71-OP73 can be performed simultaneously. For another example, the operation OP73 can be performed before the operation OP72, and the operation OP72 can be performed before the operation OP71.

During the operation OP71, a first conductive segment for connecting a first logic cell to a second logic cell is formed. For example, the conductive segment ILM1 for connecting the logic cell CL1 to the logic cell CL2 is formed.

During the operation OP72, a first layer including a first switch of the first logic cell and a second switch of the second logic cell is formed. For example, the layer LN1 including the switch TN1 of the logic cell CL1 and the switch TN2 of the logic cell CL2 is formed.

During the operation OP73, a second layer including a third switch of the first logic cell and a fourth switch of the second logic cell is formed. For example, the layer LP1 including the switch TP1 of the logic cell CL1 and the switch TP2 of the logic cell CL2 is formed.

In some embodiments, the operation OP72 further includes forming a first isolation structure at a boundary between the first logic cell and the second logic cell. For example, the isolation structure IT1 is formed at a boundary between the logic cells CL1 and CL2.

In some embodiments, the operation OP73 further includes forming a second isolation structure at the boundary between the first logic cell and the second logic cell. For example, the isolation structure IB1 is formed at the boundary between the logic cells CL1 and CL2.

In some embodiments, the operation OP72 further includes forming a gate structure of the first switch, and forming a second conductive segment of the second switch. For example, the gate structure GT1 of the switch TN1 is formed, and the conductive segment MT3 of the switch TN2 is formed.

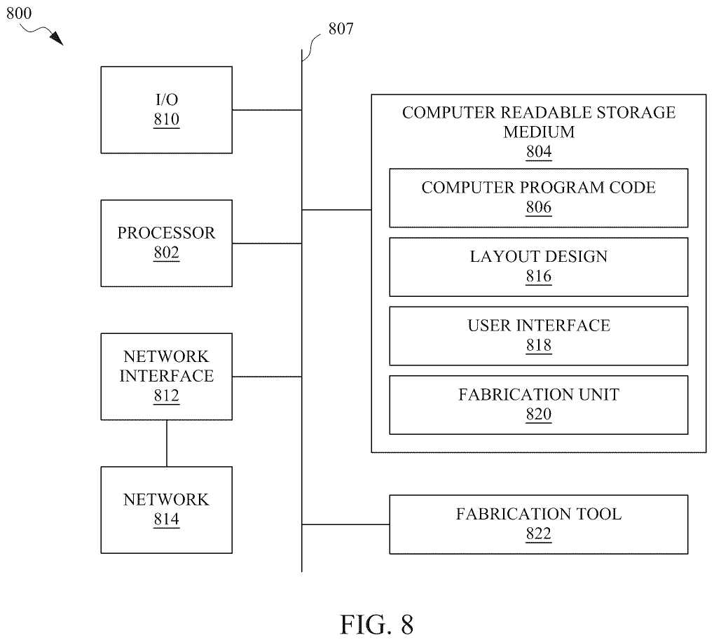

FIG. 8 is a schematic view of a system 800 for designing and manufacturing at least one of the semiconductor devices as described herein, in accordance with some embodiments of the present disclosure. The system 800 generates or places one or more IC layout designs corresponding to at least one of the semiconductor devices as described herein. In some embodiments, the system 800 manufactures one or more semiconductor devices based on the one or more IC layout designs, as described herein. The system 800 includes a hardware processor 802 and a non-transitory, computer readable storage medium 804 encoded with, e.g., storing, the computer program code 806, e.g., a set of executable instructions. The computer readable storage medium 804 is configured for interfacing with manufacturing machines for producing the semiconductor device. The processor 802 is electrically coupled to the computer readable storage medium 804 by a bus 807. The processor 802 is also electrically coupled to an I/O interface 810 by the bus 807. A network interface 812 is also electrically connected to the processor 802 by the bus 807. Network interface 812 is connected to a network 814, so that the processor 802 and the computer readable storage medium 804 are capable of connecting to external elements via network 814. The processor 802 is configured to execute the computer program code 806 encoded in the computer readable storage medium 804 in order to cause the system 800 designing and manufacturing at least one of the semiconductor devices as described herein.

In some embodiments, the processor 802 is a central processing unit (CPU), a multi-processor, a distributed processing system, an application specific integrated circuit (ASIC), and/or a suitable processing unit.

In some embodiments, the computer readable storage medium 804 is an electronic, magnetic, optical, electromagnetic, infrared, and/or a semiconductor system (or apparatus or device). For example, the computer readable storage medium 804 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 804 includes a compact disk-read only memory (CD-ROM), a compact disk-read/write (CD-R/W), and/or a digital video disc (DVD).

In some embodiments, the storage medium 804 also stores information needed for designing and manufacturing at least one of the semiconductor devices as described herein, such as layout design 816, user interface 818, fabrication unit 820, and/or a set of executable instructions to designing and manufacturing at least one of the semiconductor devices as described herein.

In some embodiments, the storage medium 804 stores instructions (e.g., the computer program code 806) for interfacing with manufacturing machines. The instructions (e.g., the computer program code 806) enable the processor 802 to generate manufacturing instructions readable by the manufacturing machines to effectively implement the semiconductor devices as described herein.

The system 800 includes the I/O interface 810. The I/O interface 810 is coupled to external circuitry. In some embodiments, the I/O interface 810 includes a keyboard, keypad, mouse, trackball, trackpad, and/or cursor direction keys for communicating information and commands to the processor 802.

The system 800 also includes the network interface 812 coupled to the processor 802. The network interface 812 allows the system 800 to communicate with the network 814, to which one or more other computer systems are connected. The network interface 812 includes wireless network interfaces such as BLUETOOTH, WIFI, WIMAX, GPRS, or WCDMA; or wired network interface such as ETHERNET, USB, or IEEE-13184. In some embodiments, the designing and manufacturing of at least one of the semiconductor devices as described herein is implemented in two or more systems 800, and information such as layout design, user interface and fabrication unit are exchanged between different systems 800 by the network 814.

The system 800 is configured to receive information related to a layout design through the I/O interface 810 or network interface 812. The information is transferred to the processor 802 by the bus 807 to determine a layout design for producing an IC. The layout design is then stored in the computer readable medium 804 as the layout design 816. The system 800 is configured to receive information related to a user interface through the I/O interface 810 or network interface 812. The information is stored in the computer readable medium 804 as the user interface 818. The system 800 is configured to receive information related to a fabrication unit through the I/O interface 810 or network interface 812. The information is stored in the computer readable medium 804 as the fabrication unit 820. In some embodiments, the fabrication unit 820 includes fabrication information utilized by the system 800.

In some embodiments, the designing and manufacturing of at least one of the semiconductor devices as described herein is implemented as a standalone software application for execution by a processor. In some embodiments, the designing and manufacturing of at least one of the semiconductor devices as described herein is implemented as a software application that is a part of an additional software application. In some embodiments, the designing and manufacturing of at least one of the semiconductor devices as described herein is implemented as a plug-in to a software application. In some embodiments, the designing and manufacturing of at least one of the semiconductor devices as described herein is implemented as a software application that is a portion of an EDA tool. In some embodiments, the designing and manufacturing of at least one of the semiconductor devices as described herein is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, at least one of the semiconductor devices as described herein is implemented by a manufacturing device to manufacture an integrated circuit using a set of masks manufactured based on one or more layout designs generated by the system 800. In some embodiments, the system 800 includes a manufacturing device (e.g., fabrication tool 822) to manufacture an integrated circuit using a set of masks manufactured based on one or more layout designs of the present disclosure.

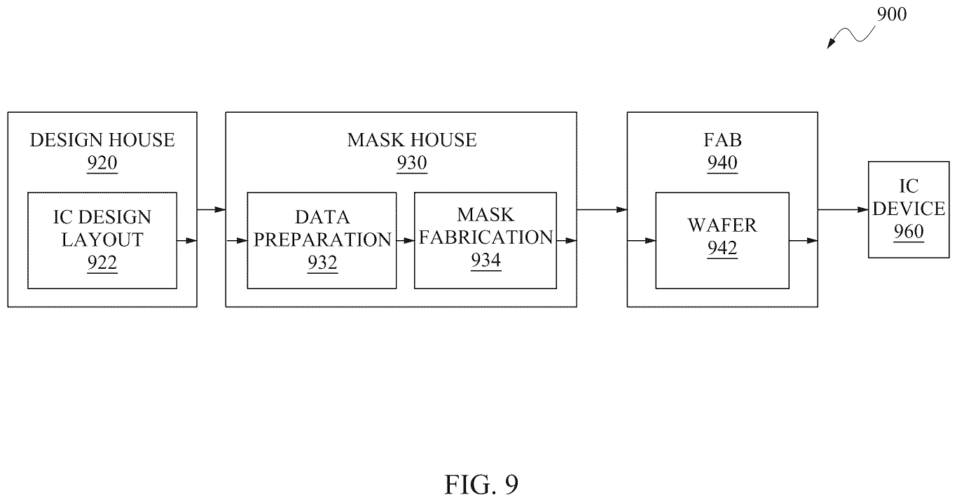

FIG. 9 is a block diagram of an integrated circuit (IC)/semiconductor device manufacturing system 900, and an IC manufacturing flow associated therewith, in accordance with some embodiments of the present disclosure. Referring to FIG. 7 and FIG. 9, the method 700 is performed by the IC manufacturing system 900 in some embodiments.

In FIG. 9, the IC manufacturing system 900 includes entities, such as a design house 920, a mask house 930, and an IC manufacturer/fabricator (“fab”) 940, that interact with one another in the design, development, and manufacturing cycles and/or services related to manufacturing an IC device (semiconductor device) 960 including at least one of the semiconductor devices as described herein. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 920, mask house 930, and IC fab 940 is owned by a single company. In some embodiments, two or more of design house 920, mask house 930, and IC fab 940 coexist in a common facility and use common resources.

The design house (or design team) 920 generates an IC design layout 922. The IC design layout 922 includes various geometrical patterns designed for the IC device 960. The geometrical patterns correspond to patterns of metal, oxide, or semiconductor layers that make up the various components of the IC device 960 to be fabricated. The various layers combine to form various IC features. For example, a portion of the IC design layout 922 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 920 implements a proper design procedure to form the IC design layout 922. The design procedure includes one or more of logic design, physical design or place and route. The IC design layout 922 is presented in one or more data files having information of the geometrical patterns. For example, the IC design layout 922 can be expressed in a GDSII file format or DFII file format.

The mask house 930 includes mask data preparation 932 and mask fabrication 934. The mask house 930 uses the IC design layout 922 to manufacture one or more masks to be used for fabricating the various layers of the IC device 960 according to the IC design layout 922. The mask house 930 performs the mask data preparation 932, where the IC design layout 922 is translated into a representative data file (“RDF”). The mask data preparation 932 provides the RDF to the mask fabrication 934. The mask fabrication 934 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 932 to comply with particular characteristics of the mask writer and/or requirements of the IC fab 940. In FIG. 9, the mask data preparation 932 and mask fabrication 934 are illustrated as separate elements. In some embodiments, the mask data preparation 932 and mask fabrication 934 can be collectively referred to as mask data preparation.

In some embodiments, the mask data preparation 932 includes optical proximity correction (OPC) which uses lithography enhancement techniques to compensate for image errors, such as those that can arise from diffraction, interference, other process effects and the like. OPC adjusts the IC design layout 922. In some embodiments, the mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 934, which may undo part of the modifications performed by OPC in order to meet mask creation rules.

In some embodiments, the mask data preparation 932 includes lithography process checking (LPC) that simulates processing that will be implemented by the IC fab 940 to fabricate the IC device 960. LPC simulates this processing based on the IC design layout 922 to create a simulated manufactured device, such as the IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 922.

It should be understood that the above description of the mask data preparation 932 has been simplified for the purposes of clarity. In some embodiments, the mask data preparation 932 includes additional features such as a logic operation (LOP) to modify the IC design layout according to manufacturing rules. Additionally, the processes applied to the IC design layout 922 during the mask data preparation 932 may be executed in a variety of different orders.

After the mask data preparation 932 and during mask fabrication 934, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 940 is an IC fabrication entity that includes one or more manufacturing facilities for the fabrication of a variety of different IC products. In some embodiments, the IC fab 940 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 940 uses the mask (or masks) fabricated by the mask house 930 to fabricate the IC device 960. Thus, the IC fab 940 at least indirectly uses the IC design layout 922 to fabricate the IC device 960. In some embodiments, a semiconductor wafer is fabricated by the IC fab 940 using the mask (or masks) to form the IC device 960. The semiconductor wafer 942 includes a silicon substrate or other proper substrate having material layers formed thereon. Semiconductor wafer further includes one or more of various doped regions, dielectric features, multilevel interconnects, and the like (formed at subsequent manufacturing steps).

Also disclosed is a device. The device includes a first layer, a second layer and a first conductive segment. The first layer corresponds to transistors of a first conductive type. The second layer corresponds to transistors of a second conductive type different from the first conductive type. The first conductive segment is disposed between and coupled to the first layer and the second layer, and configured to connect a first logic cell to a second logic cell. Each of the first logic cell and the second logic cell corresponds to the first layer and the second layer.

Also disclosed is a device. The device includes a first logic cell, a second logic cell and a first conductive segment. The first logic cell at least includes a first switch disposed in a first layer and a second switch disposed in a second layer. The second logic cell at least includes a third switch disposed in the first layer and a fourth switch disposed in the second layer. The first conductive segment is disposed between the first layer and the second layer, and coupled to each of the first switch, the second switch, the third switch and the fourth switch.

Also disclosed is a method. The method includes: forming a first conductive segment for connecting a first logic cell to a second logic cell; forming a first layer comprising a first switch of the first logic cell and a second switch of the second logic cell; forming a second layer comprising a third switch of the first logic cell and a fourth switch of the second logic cell. The first conductive segment is disposed between the first layer and the second layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first layer corresponding to transistors of a first conductive type;
a second layer corresponding to transistors of a second conductive type different from the first conductive type; and
a first conductive segment disposed between and coupled to the first layer and the second layer, and configured to connect a first logic cell to a second logic cell,
each of the first logic cell and the second logic cell corresponds to the first layer and the second layer.

2. The device of claim 1, wherein the first layer comprises:
a first isolation structure disposed at a boundary between the first logic cell and the second logic cell,
wherein the first conductive segment is overlapped with the first isolation structure.

3. The device of claim 2, wherein the second layer comprises:
a second isolation structure disposed at the boundary,
wherein the first conductive segment is disposed between the first isolation structure and the second isolation structure.

4. The device of claim 2, wherein the first layer further comprises:
a second conductive segment coupled to the first conductive segment; and
a first gate structure coupled to the first conductive segment,
wherein the first isolation structure is disposed between the second conductive segment and the first gate structure.

5. The device of claim 1, wherein the first layer comprises:
a first switch of the first logic cell; and
a second switch of the second logic cell,
wherein the first conductive segment is coupled to each of the first switch and the second switch.

6. The device of claim 5, wherein the second layer comprises:
a third switch of the first logic cell,
wherein the first conductive segment is disposed between the first switch and the third switch, and is further coupled to the third switch.

7. The device of claim 5, wherein the first layer further comprises:
an isolation structure disposed between the first switch and the second switch.

8. The device of claim 1, further comprising:
a plurality of first via structures configured to couple the first conductive segment to the first layer; and
a plurality of second via structures configured to couple the first conductive segment to the second layer,
wherein upper edges of the plurality of first via structures are longer than lower edges of the plurality of first via structures, and
upper edges of the plurality of second via structures are longer than lower edges of the plurality of second via structures.

9. The device of claim 1, further comprising:
a plurality of first via structures configured to couple the first conductive segment to the first layer; and
a plurality of second via structures configured to couple the first conductive segment to the second layer,
wherein upper edges of the plurality of first via structures are shorter than lower edges of the plurality of first via structures, and
upper edges of the plurality of second via structures are shorter than lower edges of the plurality of second via structures.

10. The device of claim 1, further comprising:
a plurality of first via structures configured to couple the first conductive segment to the first layer; and
a plurality of second via structures configured to couple the first conductive segment to the second layer,
wherein upper edges of the plurality of first via structures are longer than lower edges of the plurality of first via structures, and
upper edges of the plurality of second via structures are shorter than lower edges of the plurality of second via structures.

11. The device of claim 1, further comprising:
a plurality of first via structures configured to couple the first conductive segment to the first layer; and
a plurality of second via structures configured to couple the first conductive segment to the second layer,
wherein upper edges of the plurality of first via structures are shorter than lower edges of the plurality of first via structures, and
upper edges of the plurality of second via structures are longer than lower edges of the plurality of second via structures.

12. A device, comprising:
a first logic cell at least comprising a first switch disposed in a first layer and a second switch disposed in a second layer;
a second logic cell at least comprising a third switch disposed in the first layer and a fourth switch disposed in the second layer; and
a first conductive segment disposed between the first layer and the second layer, and coupled to each of the first switch, the second switch, the third switch and the fourth switch.

13. The device of claim 12, further comprising:
a first isolation structure disposed at a boundary between the first logic cell and the second logic cell, and disposed in the first layer; and
a second isolation structure disposed at the boundary, and disposed in the second layer,
wherein the first conductive segment is disposed between the first isolation structure and the second isolation structure.

14. The device of claim 12, further comprising:
a second conductive segment disposed at a boundary between the first logic cell and the second logic cell, and disposed in the first layer; and
a third conductive segment disposed at the boundary, and disposed in the second layer,
wherein the first conductive segment is configured to receive a first reference voltage signal and a second reference voltage signal from the second conductive segment and the third conductive segment, respectively, and
the first reference voltage signal and the second reference voltage signal are different from each other.

15. The device of claim 12, further comprising:
a second conductive segment coupled to the first conductive segment, disposed in the first layer, and corresponding to the third switch; and
a first gate structure coupled to the first conductive segment, disposed in the second layer, and corresponding to the second switch.

16. The device of claim 15, further comprising:
a third conductive segment coupled to the first conductive segment, disposed in the second layer, and corresponding to the fourth switch; and
a second gate structure coupled to the first conductive segment, disposed in the first layer, and corresponding to the first switch.

17. A method, comprising:
forming a first conductive segment for connecting a first logic cell to a second logic cell;
forming a first layer comprising a first switch of the first logic cell and a second switch of the second logic cell; and
forming a second layer comprising a third switch of the first logic cell and a fourth switch of the second logic cell,
wherein the first conductive segment is disposed between the first layer and the second layer.

18. The method of claim 17, wherein forming the first layer comprises:
forming a first isolation structure at a boundary between the first logic cell and the second logic cell,
wherein the first conductive segment is overlapped with the first isolation structure.

19. The method of claim 18, wherein forming the second layer comprises:
forming a second isolation structure at the boundary,
wherein the first conductive segment is disposed between the first isolation structure and the second isolation structure.

20. The method of claim 18, wherein forming the first layer further comprises:
forming a gate structure of the first switch; and
forming a second conductive segment of the second switch,
wherein the first conductive segment is coupled to each of the gate structure and the second conductive segment.
